(19) United States
(12) Patent Application Publication
(10) Pub. No.: US 2014/0379967 A1
(43) Pub. Date: Dec. 25, 2014

(54) CLOCK SIGNAL GENERATOR FOR A DIGITAL CIRCUIT

(71) Applicant: FENTON SYSTEMS LTD, Rickmansworth, Hertfordshire (GB)

(72) Inventor: Martin Calder, Oxfordshire (GB)

(73) Assignee: FENTON SYSTEMS LTD, Rickmansworth, Hertfordshire (UK)

(21) Appl. No.: 14/370,915

(22) PCT Filed: Jan. 9, 2013
(86) PCT No.: PCT/GB2013/050027

§ 371 Date: Jul. 7, 2014

(30) Foreign Application Priority Data
Jan. 9, 2012 (GB) 1200219.2

(51) Int. Cl. G06F 1/08; G11C 7/10; G11C 16/32; G06F 12/08

(52) U.S. Cl. CPC G06F 1/08; G06F 12/0893; G11C 7/1072; G11C 16/32
USPC 711/103; 713/501; 711/119; 711/104

(57) ABSTRACT

A computer has a mother board upon which is mounted, a millimetre wave oscillator and a central processing unit (CPU). The millimetre wave oscillator is operable to generate a clock signal and transmit this to the CPU via a link. The clock signal may be employed as a system clock signal and a processing clock signal for the CPU. The millimetre wave oscillator allows higher frequency clock signals than are currently available whilst generating significantly less heat. Therefore, the CPU may not require any cooling system and if it does then a smaller cooling system than is required by the prior art will suffice. Furthermore, the CPU will be more stable. This arrangement requires less power than prior art arrangements and therefore may increase the battery life of a computer.

### TECHNICAL FIELD OF THE INVENTION

The present invention relates to a clock signal generator for a digital circuit and an associated method. In particular, it relates to a novel clock signal generator for synchronising a central processing unit (CPU) of a computer.

### BACKGROUND TO THE INVENTION

Many types of digital circuits utilise a clock signal to coordinate changes in the state of its various components. Such a clock signal is typically a digital signal implemented as a square wave form. In particular, in modern computers a microprocessor is provided with a clock signal generating mechanism to coordinate all of the computational steps that it performs. The rise and/or fall of the square wave form may signal the start of a new set of computational steps. The frequency of the clock signal may be chosen to be sufficiently low for any computational step to be performed in a single clock cycle by estimating the worst case scenario for signal propagation through the microprocessor.

A typical clock signal generating mechanism comprises an oscillating piezoelectric crystal, such as a quartz crystal. An oscillating voltage is applied across the crystal to drive the oscillations at its resonant frequency. Initially, a superposition of a range of frequencies may be employed and the crystal will naturally oscillate at its resonant frequency. The signal may be amplified and a fraction thereof may be used to continue to drive the oscillations.

Modern computers are provided with a plurality of synchronised clocks which may run at different frequencies. This allows different operations to be performed at different rates. For example, the retrieval of information from memory typically runs at a slower rate than the central processing unit (CPU). The main clock signal for a computer is its system clock, which often comprises an oscillating piezoelectric crystal and is located on the computer's motherboard. The CPU is provided with a clock signal generating mechanism that is operable to multiply the frequency of the system clock signal by a clock multiplier factor. This is typically an integer or half integer factor. In a typical set up two pins of the microprocessor in a computer are connected to an oscillator circuit comprising a quartz crystal oscillator and a system of capacitors. Alternatively, some microprocessors are provided with an internal oscillator.

Since the clock located on, or connected to, the processor controls the rate at which the processor executes commands it is desirable for the frequency of the clock signal that it generates to be as high as possible. However, the oscillators described above and in particular crystal oscillators generate a significant amount of heat. The higher the frequency the greater the amount of heat that is produced and the greater the need for the processor to be cooled will be. Higher frequencies also require greater power to drive the oscillator. As such, there is often a tension between the desire for higher frequencies one the one hand and the reduction in the stability of the processor and the requirement for an efficient cooling system on the other hand.

It is therefore an object of embodiments of the present invention to address these problems.

### SUMMARY OF THE INVENTION

According to a first aspect of the present invention there is provided an apparatus comprising: a digital circuit; and a clock generating mechanism operable to produce a clock signal, characterised in that the clock generating mechanism comprises a millimetre wave oscillator.

Advantageously, a millimetre wave oscillator allows higher frequency clock signals than are currently available in the prior art whilst generating significantly less heat. Therefore, the digital circuit may not require any cooling system and if it does a smaller cooling system than is required by the prior art will suffice. Furthermore, the digital circuit will be more stable than prior art circuits. This arrangement requires less power than prior art arrangements and therefore may increase the battery life of any portable devices incorporating a digital circuit according to the present invention.

The digital circuit and the millimetre wave oscillator may be formed as a single component or, alternatively, as separate components. In particular, the digital circuit and the millimetre wave oscillator may each be formed as a separate component each of which is mounted on a circuit board. The circuit board may be a motherboard of a computer.

The digital circuit and the millimetre wave oscillator may be connected via any suitable link. This allows the clock signal generated by the millimetre wave oscillator to be transmitted to the digital circuit. The link may comprise a wireless link. Such a wireless link may comprise a transmitter disposed on the millimetre wave oscillator and a receiver disposed on the digital circuit. Alternatively, the link may comprise a physical link. Said physical link may comprise any or all of the following components: coaxial cables, waveguides, wave cavities and connectors as desired and/or required.

The digital circuit may be an integrated circuit. The integrated circuit may be a processor. The processor may be the central processing unit for a computer.

The millimetre wave oscillator may comprise a Super High Frequency (SHF) or an Extremely High Frequency (EHF) transmitter. Advantageously, embodiments employing these transmitters will have very low heat emission and therefore may not require any cooling system. Furthermore, such embodiments allow for the generation of clock signals with a frequency of up to around 300 GHz, a significant improvement on prior art clock rates.

Alternatively, the millimetre wave oscillator may utilise light wave technology. In particular, the millimetre wave oscillator may comprise an infra-red or near visible transmitter. Such embodiments allow extremely high clock signal frequencies, up to around 400 THz. For such embodiments, the apparatus may additionally comprise a cooling means, if desired.

The millimetre wave oscillator may operate in a near vacuum. Advantageously, this may reduce any external interference.

The digital circuit may comprise one or more memory caches. Said memory caches may comprise random access memory (RAM). Preferably, the memory caches comprise non-volatile memory. Advantageously, this provides protection against losses of power and/or power spikes. The non-volatile memory caches may comprise magnetoresistive random access memory (MRAM) and/or spintronics technology.

The apparatus may further comprise a data bus. The data bus may be connected to the digital circuit. Advantageously, this allows the digital circuit to be connected to any other computer components. The data bus may comprise any suitable technology to transfer data to and/or from the digital circuit. Suitable modern technologies for transferring data to and/or from the digital circuit include, but are not limited to, the following: Infiniband EDR/HDR/NDR, line-of-sight optics or infrared wavelength morse.

The apparatus may comprise a shielding means. The shielding means may be operable to shield the apparatus from external millimetre wave sources. Additionally or alternatively, the shielding means may be operable to shield external objects from millimetre wave emissions originating from the millimetre wave oscillator.

According to a second aspect of the present invention there is provided a computer comprising a motherboard and an apparatus according to the first aspect of the present invention wherein the millimetre wave oscillator and the digital circuit are each mounted on the motherboard and the digital circuit forms the central processing unit of the computer.

The computer according to the second aspect of the present invention may incorporate any or all features of the digital circuit according to the first aspect of the present invention as is desired or appropriate.

Advantageously, the digital circuit according to the first aspect of the present invention allows the computer to operate at significantly higher clock speeds than prior art computers.

The millimetre wave oscillator may provide the clock signal for the central processing unit. Preferably, the millimetre wave oscillator also provides the main clock signal for the computer. Advantageously, with such an arrangement the central processing unit does not require an additional clock signal generating mechanism. Therefore, in order to operate the central processing unit less power is required and the battery life of the computer may be increased significantly. Furthermore, less heat is generated and therefore less cooling, if any, will be required and the central processing unit can be smaller. The millimetre wave oscillator therefore allows higher processing speeds than are currently available in the prior art.

Preferably, the digital circuit and the millimetre wave oscillator are formed as separate components and located on different areas of the motherboard. Preferably, the millimetre wave oscillator is sufficiently separated from central processing unit so as not to be in thermal contact therewith. Advantageously, this further reduces the need for a cooling system to regulate the temperature of the central processing unit.

The digital circuit and the millimetre wave oscillator may be connected via any suitable link. This allows the clock signal generated by the millimetre wave oscillator to be transmitted to the digital circuit. The link may comprise a wireless link. Such a wireless link may comprise a transmitter disposed on the millimetre wave oscillator and a receiver disposed on the digital circuit. Alternatively, the link may comprise a physical link. Said physical link may comprise any or all of the following components: coaxial cables, waveguides, wave cavities and connectors.

The central processing unit may comprise one or more memory caches. Said memory caches may comprise random access memory (RAM). Preferably, the memory caches comprise non-volatile memory. Advantageously, this provides protection against losses of power and/or power spikes. The non-volatile memory caches may comprise magnetoresistive random access memory (MRAM) and/or spintronics technology.

The computer may further comprise a data bus. The data bus may be connected to the digital circuit. Advantageously, this allows the digital circuit to be connected to any other computer components. The data bus may comprise any suitable technology to transfer data to and/or from the digital circuit. Suitable modern technologies for transferring data to and/or from the digital circuit include, but are not limited to, the following: Infiniband EDR/HDR/NDR, line-of-sight optics or infrared wavelength morse.

The computer may comprise a shielding means. The shielding means may be operable to shield at least part of the computer from external millimetre wave sources. Additionally or alternatively, the shielding means may be operable to shield external objects from millimetre wave emissions originating from the millimetre wave oscillator.

The computer may comprise any combination of known computer elements as would be obvious to one skilled in the art.

According to a third aspect of the present invention there is provided a computer comprising a motherboard, a central processing unit and a clock signal generating mechanism, wherein the central processing unit and the clock signal generating mechanism are both mounted on the motherboard, characterised in that the clock signal generating mechanism comprises a millimetre wave oscillator and is sufficiently separated from central processing unit so as not to be in thermal contact therewith.

The computer according to the third aspect of the present invention may incorporate any or all features of the digital circuit according to the first aspect of the present invention or the computer according to the second aspect of the present invention as is desired or appropriate.

Such an arrangement reduces the need for a cooling system to regulate the temperature of the central processing unit.

### DETAILED DESCRIPTION OF THE INVENTION

In order that the invention can be more clearly understood embodiments thereof are now described further below, by way of example, with reference to the accompanying drawings, of which:

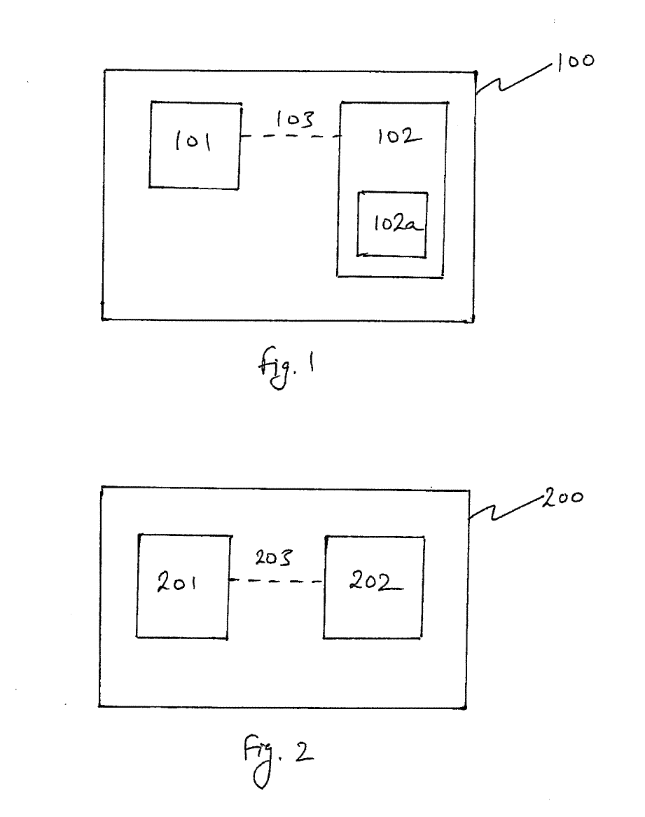

FIG. 1 shows a schematic of a motherboard of a prior art computer; and

FIG. 2 shows a schematic of a motherboard of a computer according to the present invention.

### Referring to FIG. 1, typically, a prior art computer comprises a motherboard 100 upon which is mounted, among other components, a system clock 101 and a central processing unit (CPU) 102.

The system clock 101 typically comprises a quartz crystal and is operable to generate a system clock signal and transmit this to the CPU 102 via a link 103.

The CPU 102 comprises a clock signal generating mechanism 102a located thereon and operable to generate a processing clock signal that is a multiple of the system clock signal. For example, the processing clock signal may have a frequency that is a factor of two or three larger than the system clock signal. The clock signal generating mechanism 102a also typically comprises an oscillating system such as a quartz crystal, which requires power and generates a significant quantity of heat. This reduces the stability of the CPU and therefore often a cooling system is required so as to ensure that the CPU 102 does not overheat. For high processing speeds, a very efficient cooling system may be required to prevent damage to the CPU 102.

The faster the clock signal generating mechanism 102a oscillates, the greater the heat generated. Therefore, in order to achieve higher processing speeds with such a prior art arrangement, more efficient cooling systems will be required.

Referring to FIG. 2, a computer according to the present invention comprises a mother board 200 upon which is mounted, among other components, a millimetre wave oscillator 201 and a central processing unit (CPU) 202.

The millimetre wave oscillator 201 is operable to generate a clock signal and transmit this to the CPU 202 via a link 203. The clock signal may be employed as a system clock signal and a processing clock signal for the CPU 202.

The link 203 may comprise any suitable link and may be either wireless or physical. For embodiments employing a physical link 203, said physical link may comprise any or all of the following components: coaxial cables, waveguides, wave cavities and connectors.

Advantageously, the millimetre wave oscillator 201 allows higher frequency clock signals than are currently available in the prior art whilst generating significantly less heat. Therefore, the CPU 202 may not require any cooling system and if it does then a smaller cooling system than is required by the prior art will suffice. Furthermore, the CPU 202 will be more stable than in arrangements. This arrangement requires less power than prior art arrangements and therefore may increase the battery life of a computer according to the present invention.

The millimetre wave oscillator 201 may comprise a Super High Frequency (SHF) or an Extremely High Frequency (EHF) transmitter. Advantageously, embodiments employing these transmitters will have very low heat emission and therefore may not require any cooling system. Furthermore, such embodiments allow for the generation of clock signals with a frequency of up to around 300 GHz, a significant improvement on prior art clock rates.

Alternatively, the millimetre wave oscillator 201 may utilise light wave technology. In particular, the millimetre wave oscillator may comprise an infra-red or near visible transmitter. Such embodiments allow extremely high clock signal frequencies, up to around 400 THz. For such embodiments, the apparatus may additionally comprise a cooling means, if desired.

The millimetre wave oscillator 201 may operate in a near vacuum. Advantageously, this may reduce any external interference.

Preferably, the millimetre wave oscillator 201 is sufficiently separated from the 202 so as not to be in thermal contact therewith. Advantageously, this further reduces the need for a cooling system to regulate the temperature of the CPU 202.

The computer may comprise a shielding means (not shown). The shielding means may be operable to shield at least part of the computer from external millimetre wave sources. Additionally or alternatively, the shielding means may be operable to shield external objects from millimetre wave emissions originating from the millimetre wave oscillator 201.

The computer may further comprise any combination of known computer elements as would be obvious to one skilled in the art.

In particular, the CPU 202 may comprise one or more memory caches. Said memory caches may comprise random access memory (RAM). Preferably, the memory caches comprise non-volatile memory. Advantageously, this provides protection against losses of power and/or power spikes. The non-volatile memory caches may comprise magnetoresistive random access memory (MRAM) and/or spintronics technology.

The CPU 202 may further comprise a data bus. The data bus may be connected to the digital circuit. Advantageously, this allows the digital circuit to be connected to any other computer components. The data bus may comprise any suitable technology to transfer data to and/or from the digital circuit. Suitable modern technologies for transferring data to and/or from the digital circuit include, but are not limited to, the following: Infiniband EDR/HDR/NDR, line-of-sight optics or infrared wavelength morse.

A computer according to the present invention offers several advantages over prior art arrangements. In particular, a computer according to the present invention has a throughput potential of 44.7 Terabytes per second and may be capable of achieving computing speeds of up to 400 THz. The use of a millimetre wave oscillator 201 results in lower heat emissions and lower power requirements, this in turn requires less cooling of the CPU 202. Furthermore, the CPU 202 is smaller due to removal of on-processor clock signal generating mechanism.

It is of course to be understood that the invention is not to be restricted to the details of the above embodiments which have been described by way of example only.

1. An apparatus comprising: a digital circuit; and a clock generating mechanism operable to produce a clock signal, characterised in that the clock generating mechanism comprises a millimetre wave oscillator.

2. An apparatus as claimed in claim 1 wherein the digital circuit and the millimetre wave oscillator are formed as a single component.

3. An apparatus as claimed in claim 1 wherein the digital circuit and the millimetre wave oscillator are formed as separate components.

4. An apparatus as claimed in claim 3 wherein the digital circuit and the millimetre wave oscillator are connected via a wireless link.

5. An apparatus as claimed in claim 4 wherein the wireless link comprises a transmitter disposed on the millimetre wave oscillator and a receiver disposed on the digital circuit.

6. An apparatus as claimed in claim 3 wherein the digital circuit and the millimetre wave oscillator are connected via a physical link.

7. An apparatus as claimed in claim 4 wherein the physical link comprises any or all of the following components: coaxial cables, waveguides, wave cavities and connectors.

8. An apparatus as claimed in any preceding claim wherein the digital circuit is an integrated circuit.

9. An apparatus as claimed in any preceding claim wherein the millimetre wave oscillator comprises a Super High Frequency (SHF) or an Extremely High Frequency (EHF) transmitter.

10. An apparatus as claimed in any preceding claim wherein the millimetre wave oscillator utilises light wave technology.

11. An apparatus as claimed in claim 10 wherein the millimetre wave oscillator comprises an infra-red or near visible transmitter.

12. An apparatus as claimed in any preceding claim wherein the apparatus additionally comprises a cooling means.

13. An apparatus as claimed in any preceding claim wherein the millimetre wave oscillator operates in a near vacuum.

14. An apparatus as claimed in any preceding claim wherein the digital circuit comprises one or more memory caches.

15. An apparatus as claimed in claim 14 wherein the memory caches comprise random access memory (RAM).

16. An apparatus as claimed in claim 14 or claim 15 wherein the memory caches comprise non-volatile memory.

17. An apparatus as claimed in any preceding claim wherein the apparatus further comprises a data bus connected to the digital circuit.

18. An apparatus as claimed in any preceding claim wherein the apparatus comprises a shielding means operable to shield the apparatus from external millimetre wave sources.

19. An apparatus as claimed in claim 18 wherein the shielding means is also operable to shield external objects from millimetre wave emissions originating from the millimetre wave oscillator.

20. A computer comprising a motherboard and an apparatus according to any preceding claim wherein the millimetre wave oscillator and the digital circuit are each mounted on the motherboard and the digital circuit forms the central processing unit of the computer.

21. A computer as claimed in claim 20 wherein the millimetre wave oscillator provides the clock signal for the central processing unit.

22. A computer as claimed in claim 20 or claim 21 wherein the millimetre wave oscillator also provides the main clock signal for the computer.

23. A computer as claimed in any one of claims 20 to 22 wherein the digital circuit and the millimetre wave oscillator are formed as separate components and located on different areas of the motherboard.

24. A computer as claimed in claim 23 wherein the millimetre wave oscillator is sufficiently separated from central processing unit so as not to be in thermal contact therewith.
